(19) United States
(12) Patent Application Publication
(10) Pub. No.: US 2026/0015723 A1
(43) Pub. Date: Jan. 15, 2026

(54) SUBSTRATE PROCESSING APPARATUS, GAS SUPPLY ASSEMBLY, SUBSTRATE PROCESSING METHOD, METHOD OF MANUFACTURING SEMICONDUCTOR DEVICE AND NON-TRANSITORY COMPUTER-READABLE RECORDING MEDIUM

(71) Applicant: Kokusai Electric Corporation, Tokyo (JP)

(72) Inventor: Yusaku OKAJIMA, Toyama (JP)

(73) Assignee: Kokusai Electric Corporation, Tokyo (JP)

(21) Appl. No.: 19/338,074

(22) Filed: Sep. 24, 2025

Related U.S. Application Data
(63) Continuation of application No. PCT/JP2023/024489, filed on Jun. 30, 2023.

(51) Int. Cl. C23C 16/455

(52) U.S. Cl. CPC C23C 16/4557; C23C 16/45561

(57) ABSTRACT

There is provided a technique that includes: a process chamber in which a substrate is processed; a first gas supply path through which a first gas is supplied to the substrate from beside the process chamber; and a first gas introduction port provided at a location heated to a predetermined temperature within the first gas supply path, wherein the first gas is introduced into the first gas supply path through the first gas introduction port.

### CROSS-REFERENCE TO RELATED PATENT APPLICATION

This application is a bypass continuation application of PCT International Application No. PCT/JP2023/024489, filed on Jun. 30, 2023, in the WIPO, the entire contents of which are hereby incorporated by reference.

### BACKGROUND

### 1. Field

The present disclosure relates to a substrate processing apparatus, a gas supply assembly, a substrate processing method, a method of manufacturing a semiconductor device and a non-transitory computer-readable recording medium.

### 2. Related Art

As a substrate processing apparatus used in a part of a manufacturing process of a semiconductor device, a batch and vertical type processing apparatus may be used. According to some related arts. the batch and vertical type processing apparatus is configured to accommodate a plurality of substrates (wafers) supported on a substrate support (boat) in a process furnace, and to perform a process on the substrates (for example, a film forming process and a heat treatment process) while supplying a gas to the substrates in the process furnace in a direction parallel to a surface of each substrate.

### SUMMARY

According to the present disclosure, there is provided a technique capable of suppressing a generation of particles in a gas supply path.

According to an embodiment of the present disclosure, there is provided a technique that includes: a process chamber in which a substrate is processed; a first gas supply path through which a first gas is supplied to the substrate from beside the process chamber; and a first gas introduction port provided at a location heated to a predetermined temperature within the first gas supply path, wherein the first gas is introduced into the first gas supply path through the first gas introduction port.

### BRIEF DESCRIPTION OF THE DRAWINGS

FIG. 1 is a diagram schematically illustrating a vertical cross-section of an exemplary configuration of a substrate processing apparatus according to one or more embodiments of the present disclosure.

FIG. 2 is a diagram schematically illustrating a horizontal cross-section of the exemplary configuration of the substrate processing apparatus according to the embodiments of the present disclosure.

FIG. 3 is a diagram schematically illustrating vertical cross-sections of exemplary configurations of a gas supply structure and a nozzle of the substrate processing apparatus according to the embodiments of the present disclosure, along a gas flow.

FIG. 4 is a diagram schematically illustrating a vertical cross-section of the nozzle when the nozzle is cut perpendicular to the gas flow.

FIG. 5 is a diagram schematically illustrating a perspective view of a gas guide structure of the substrate processing apparatus to the embodiments of the present disclosure.

FIG. 6 is a diagram schematically illustrating a vertical cross-section of a substrate support according to the embodiments of the present disclosure.

FIG. 7A is a diagram schematically illustrating a gas molecule capable of being used in the embodiments of the present disclosure, FIG. 7B is a diagram schematically illustrating another gas molecule capable of being used in the embodiments of the present disclosure, and FIG. 7C is a diagram schematically illustrating still another gas molecule capable of being used in the embodiments of the present disclosure

FIG. 8 is a diagram schematically illustrating a controller and related components of the substrate processing apparatus according to the embodiments of the present disclosure.

FIG. 9 is a flow chart schematically illustrating a process flow of a substrate processing according to the embodiments of the present disclosure.

### DETAILED DESCRIPTION

Hereinafter, one or more embodiments (also simply referred to as “embodiments”) according to the technique of the present disclosure will be described with reference to the drawings. The drawings used in the following descriptions are all schematic. For example, a relationship between dimensions of each component and a ratio of each component shown in the drawing may not always match the actual ones. Further, even between the drawings, the relationship between the dimensions of each component and the ratio of each component may not always match. In the drawing, a direction of an arrow “U” indicates a vertical upward direction, and a direction of an arrow “D” indicates a vertical downward direction.

### (1) Configuration of Substrate Processing Apparatus

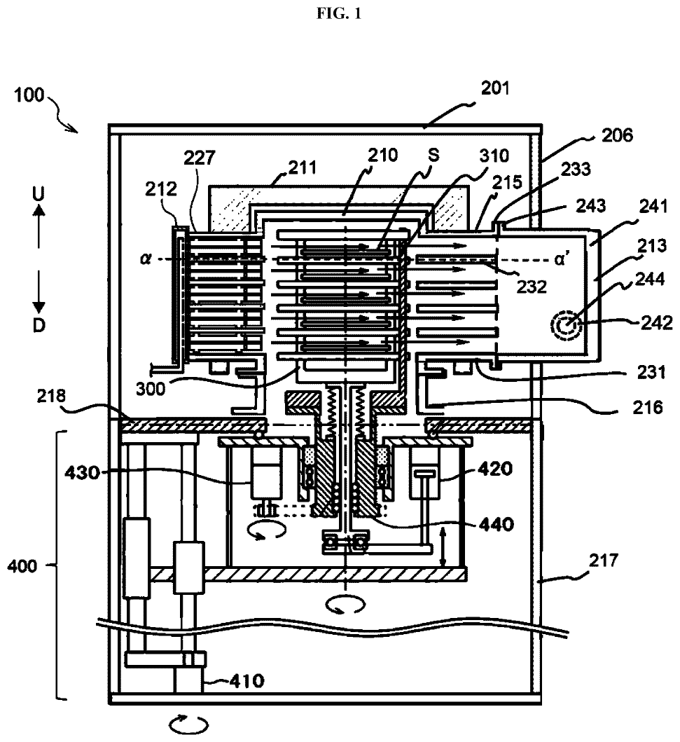

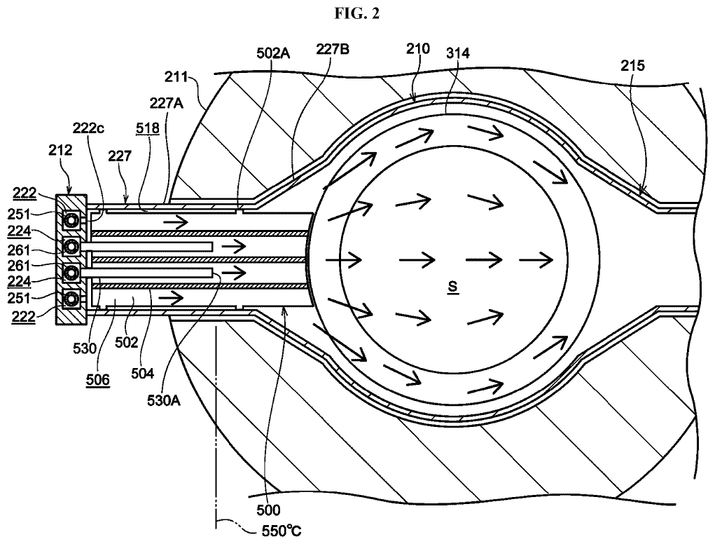

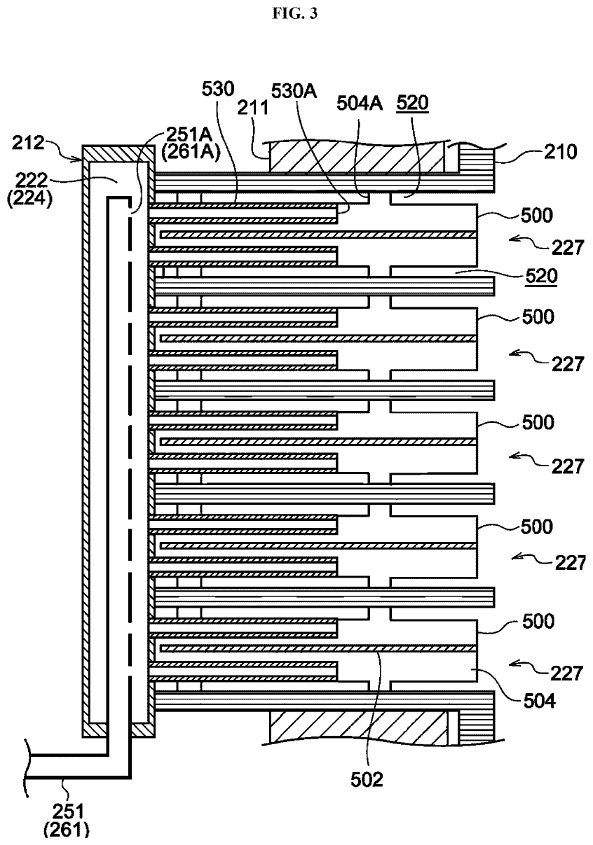

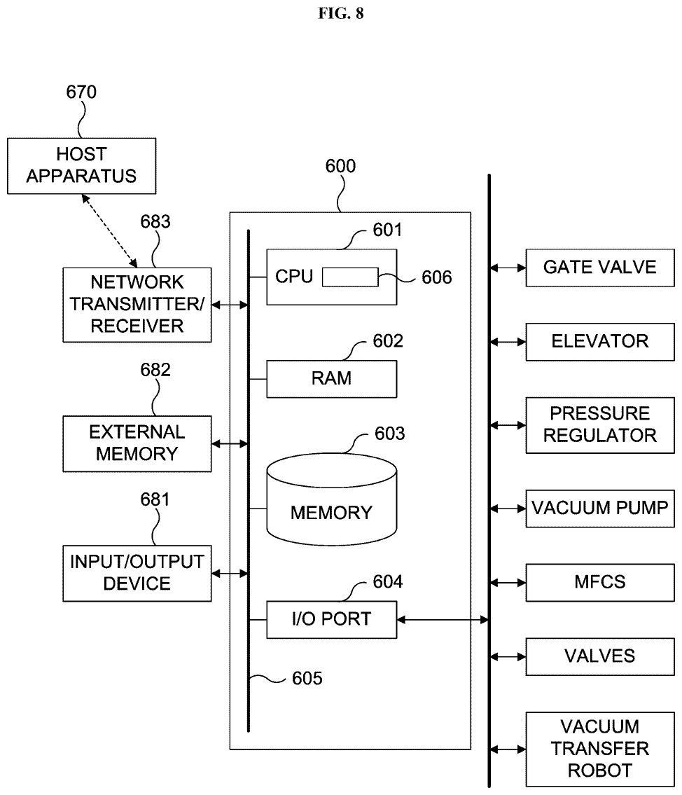

Hereinafter, an outline of a substrate processing apparatus 100 according to the embodiments of the present disclosure will be described with reference to FIGS. 1 to 9. FIG. 1 is a diagram schematically illustrating a vertical cross-section of the substrate processing apparatus 100, and FIG. 2 is a diagram schematically illustrating a horizontal cross-section of the substrate processing apparatus 100, taken along a line α-α′ in FIG. 1. FIG. 3 is a diagram schematically illustrating a relationship among a gas supply structure 212, a gas supplier 227, a reaction tube 210 and a heater 211.

Subsequently, the substrate processing apparatus 100 will be described in detail. As shown in FIG. 1, the substrate processing apparatus 100 includes a housing 201, and the housing 201 includes a reaction tube storage chamber 206 and a transfer chamber 217. The reaction tube storage chamber 206 is arranged on the transfer chamber 217.

In the reaction tube storage chamber 206, the reaction tube 210 of a cylindrical shape extending in a vertical direction, the heater 211 serving as a heating structure (furnace body) installed on an outer periphery of the reaction tube 210, the gas supply structure 212 and the gas supplier 227 configured to supply a gas (that is, the gas is supplied through the gas supply structure 212 and the gas supplier 227) and a gas exhaust structure 213 configured to exhaust the gas (that is, the gas is exhausted through the gas exhaust structure 213) are provided. In the present specification, the reaction tube 210 may also be referred to as a “process chamber”, and a space (inner space) of the reaction tube 210 may also be referred to as a “process space”. The reaction tube 210 is configured to be capable of storing a substrate support 300 described later. The gas supplier 227 constitutes a housing structure in which a gas guide structure 500 described later is accommodated.

The heater 211 is provided with a resistance heating heater (not shown) on an inner surface thereof facing the reaction tube 210, and a heat insulator (not shown) is provided so as to surround the heater 211 (that is, the resistance heating heater). Thereby, an external portion of the heater 211 (that is, a portion that does not face the reaction tube 210) is configured to be less affected by a heat. A heater controller (not shown) is electrically connected to the resistance heating heater of the heater 211. By controlling the heater controller 211a, it is possible to control a turn-on/turn-off (also simply referred to as an “ON/OFF”) of the heater 211 and a heating temperature of the heater 211. The heater 211 is capable of heating the gas described later to a temperature at which the gas is capable of being thermally decomposed. In addition, the heater 211 may also be referred to as a “process chamber heater”.

As shown in FIGS. 1 to 3, the gas supply structure 212 and the gas supplier 227 are is provided at an upstream side of the reaction tube 210 in a gas flow direction, and the gas is supplied into the reaction tube 210 in a horizontal direction through the gas supply structure 212 and the gas supplier 227. The gas exhaust structure 213 is provided at a downstream side of the reaction tube 210 in the gas flow direction, and the gas in the reaction tube 210 is discharged (exhausted) through the gas exhaust structure 213. In addition, the gas supply structure 212 and the gas supplier 227 are fixed so as to be separable. For example, a plurality of gas suppliers including the gas supplier 227 may be provided. Hereinafter, the plurality of gas suppliers including the gas supplier 227 may also be referred to as “gas suppliers 227”.

In addition, a downstream side gas guide 215 configured to adjust a flow of the gas discharged from the reaction tube 210 is provided between the reaction tube 210 and the gas exhaust structure 213. A lower end of the reaction tube 210 is supported by a manifold 216.

The reaction tube 210, the gas supplier 227 and the downstream side gas guide 215 are implemented as a continuous structure such that they communicate with one another in the horizontal direction. For example, each of the reaction tube 210, the gas supplier 227 and the downstream side gas guide 215 is made of a material such as quartz and silicon carbide (SiC). In addition, each of the reaction tube 210, the gas supplier 227 and the downstream side gas guide 215 is constituted by a heat transmittable structure capable of transmitting a heat radiated from the heater 211. The heat of the heater 211 can heat the gas and a substrate S used in a semiconductor device. For example, a plurality of substrates including the substrate S may be provided.

Hereinafter, the plurality of substrates including the substrate S may also be referred to as “substrates S”.

The gas supply structure 212 is provided inner than the gas supplier 227 when viewed from the reaction tube 210. As shown in FIG. 2, the gas supply structure 212 includes: a distributor 222 capable of communicating with a gas supply pipe 251 described later; and a distributor 224 capable of communicating with a gas supply pipe 261 described later. In addition, the distributor 222 and the distributor 224 serve as passages in the vertical direction, and are configured to distribute each gas to each of the gas suppliers 227. Therefore, the distributor 222 and the distributor 224 may also be collectively or individually referred to as a “gas distributor”.

For example, a plurality of distributors including the distributor 222 may be provided so as to be capable of communicating with the gas supply pipe 251. Hereinafter, the plurality of distributors including the distributor 222 may also be referred to as “distributors 222”. In addition, a plurality of distributors including the distributor 224 may be provided so as to be capable of communicating with the gas supply pipe 261. Hereinafter, the plurality of distributors including the distributor 224 may also be referred to as “distributors 224”. As shown in FIG. 2, the gas supply structure 212 is provided with two distributors 222 on both sides thereof in a width direction, and provided with two distributors 224 on a central portion thereof.

As shown in FIGS. 2 and 3, a part of a downstream side (downstream portion) of the gas supply pipe 251 (which is an example of a part of a gas supply system) is inserted into the distributor 222, and a part of a downstream side (downstream portion) of the gas supply pipe 261 (which is an example of a part of the gas supply system) is inserted into the distributor 224. A plurality of holes 251A through which the gas is ejected are provided at an interval in the vertical direction on a side surface of the gas supply pipe 251, and a plurality of holes 261A through which the gas is ejected are provided at an interval in the vertical direction on a side surface of the gas supply pipe 261. Each of the holes 251A and each of the holes 261A may also be referred to as an “opening”.

As shown in FIGS. 2 to 4, on a downstream side of the gas supply structure 212, the gas suppliers 227 of a cylindrical shape are stacked in the vertical direction, which is the same direction as a stacking direction of the substrate S described later. The gas suppliers 227 are provided in a multistage manner in a height direction of a substrate retainer described later. For example, the gas suppliers 227 may also be described as the “gas supplier 227” whose inner portion is divided into a plurality of flow paths in the vertical direction.

As described later, different types of gases are supplied to the gas supply pipes 251 and 261.

As shown in FIGS. 2 and 3, on a side surface of the gas supply structure 212 facing the gas supplier 227, a plurality of ejection holes 222c (which serve as an example of a second gas introduction port communicating with the distributor 222) are provided at an interval in the vertical direction, and a plurality of ejection holes 224c communicating with the distributor 224 are provided at an interval in the vertical direction. Hereinafter, each of the plurality of ejection holes 222c may also be referred to as an “ejection hole 222c”.

### <Structure of Gas Supplier>

As shown in FIG. 2, the gas supplier 227 is provided on a side surface of the reaction tube 210. The gas supplier 227 is constituted by: a straight structure 227A extending linearly from the gas supply structure 212 toward the reaction tube 210; and an expanding structure 227B provided at the straight structure 227A facing the reaction tube 210 and gradually expanding toward the reaction tube 210. In addition, the gas supplier 227 may also be referred to as a “gas ejection structure” through which the gas is ejected.

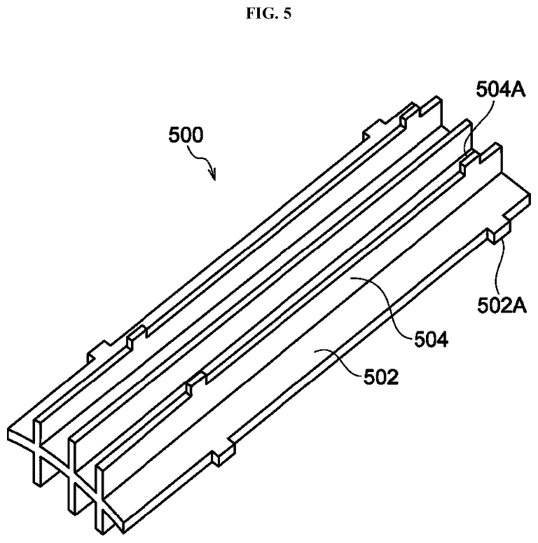

As shown in FIGS. 2 to 4, the gas guide structure 500 serving as an example of a gas supply assembly shown in FIG. 5 is accommodated inside the gas supplier 227 serving as an example of a part of the housing structure. For example, the gas guide structure 500 is constituted by a horizontal plate structure 502 and a plurality of vertical plate structures 504 serving as an example of partitions (partition walls). For example, the vertical plate structures 504 may be constituted by six vertical plate structures, that is, three vertical plate structures provided on an upper surface of the horizontal plate structure 502 and three vertical plate structures provided on a lower surface of the horizontal plate structure 502. Hereinafter, each of the vertical plate structures 504 may also be referred to as a “vertical plate structure 504”. With such a configuration, for example, eight gas introduction structures 506 are provided inside the gas supplier 227. Each of the gas introduction structures 506 serves as a passage through which the gas passes. In addition, a portion of the gas supplier 227 where the gas guide structure 500 is arranged may be referred to as a “gas guide”. Hereinafter, each of the gas introduction structures 506 may also be referred to as a “gas introduction structure 506”.

In addition, the two gas introduction structures 506 located at a laterally central portion of the gas supplier 227 in a width direction thereof serve as an example of a first gas supply path of the present disclosure, and the two gas introduction structures 506 provided on both sides of the gas supplier 227 in the width direction thereof serve as an example of a second gas supply path of the present disclosure.

In addition, in the substrate processing apparatus 100 of the present embodiments, a slight gap is provided between the gas guide structure 500 and the gas supply structure 212. However, such a gap may not be provided.

As shown in FIGS. 2 to 4, inside the two gas introduction structures 506 located at the laterally central portion of each of the gas supplier 227, a gas introduction nozzle 530 constituted by a pipe structure serving as an example of a first gas introduction structure is arranged along a longitudinal direction of the gas introduction structure 506. The gas introduction nozzle 530 serves as an example of a nozzle of the present disclosure.

One end of the gas introduction nozzle 530 is inserted and fixed into the gas supply structure 212 and communicates with the distributor 224, and is configured such that the gas supplied through the gas supply pipe 261 is ejected through the other end 530A (in other words, a front end (tip) at a downstream side or a gas ejection port, hereinafter, also referred to as a “front end” as appropriate) into the gas introduction structure 506. In addition, the gas introduction nozzle 530 is made of a material such as quartz and SiC. The front end 530A of the gas introduction nozzle 530 serves as an example of a first gas introduction port of the present disclosure. In addition, the front end 530A of the gas introduction nozzle 530 may also be referred to as the “gas ejection port”.

Therefore, as shown in FIG. 2, a distance between the front end 530A (which serves as an example of the first gas introduction port) and the substrate S is set to be shorter than a distance between the ejection hole 222c (which serves as an example of the second gas introduction port) of the gas supply structure 212 and the substrate S.

A part of a downstream side (downstream portion) of the gas supplier 227 accommodating the gas guide structure 500 is provided inner than an outer peripheral portion of the heater 211. The part of the downstream side of the gas supplier 227 and the gas guide structure at the downstream side are heated by the heater 211 to a high temperature. Thus, a temperature of a part of the gas supplier 227 (that is, a part disposed outer than the outer peripheral portion of the heater 211) is set to be lower than a temperature of a part of the gas supplier 227 (that is, a part disposed inner than the outer peripheral portion of the heater 211).

According to the present embodiments, the front end 530A of the gas introduction nozzle 530 is disposed at a location of the gas suppler 227 where a temperature of the location reaches a predetermined temperature. For example, according to the present embodiments, the term “predetermined temperature” refers to a temperature at which a first element-containing gas (according to the present embodiments, a nitrogen-containing gas) serving as a first gas does not adhere to the gas suppler 227 and the gas guide structure 500. In other words, the front end 530A of the gas introduction nozzle 530 is disposed at a location where the temperature of the location is high enough to prevent the first element-containing gas (according to the present embodiments, the nitrogen-containing gas) from adhering to the gas suppler 227 and the gas guide structure 500.

As shown in FIG. 2, the vertical plate structure 504 extends linearly along the longitudinal direction of the gas guide structure 500.

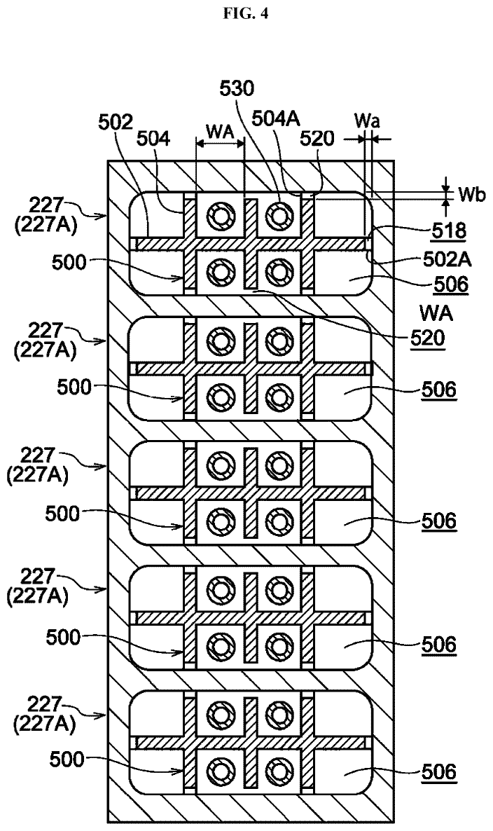

As shown in FIG. 4, according to the present embodiments, cross-sectional areas (that is, areas when viewed from a cross section perpendicular to the gas flow) of the gas introduction structures 506 arranged in the straight structure 227A of the gas supplier 227 are substantially approximately the same.

As shown in FIGS. 2, 3 and 5, two convex portions (which are protrusions) 502A are provided at a distance from each other on each side end of the horizontal plate structure 502 in a width direction thereof. The two convex portions 502A abut against (that is, contact with) an inner wall surface of the gas supplier 227. Thereby, as shown in FIG. 4, a communication portion (communication structure) 518 of a width Wa is provided between the side end of the horizontal plate structure 502 and the inner wall surface of the gas supplier 227. The communication portion 518 may be provided partially between the side end of the horizontal plate structure 502 and the inner wall surface of the gas supplier 227. Instead of the two convex portions 502A, a convex portion or three or more convex portions may be provided between the side end of the horizontal plate structure 502 and the inner wall surface of the gas supplier 227.

Two convex portions (which are protrusions) 504A are provided at a distance from each other on each end of both lateral sides of the vertical plate structure 504. The two convex portions 504A abut against (that is, contact with) the inner wall surface of the gas supplier 227. Thereby, as shown in FIG. 4, a communication portion (communication structure) 520 of a width Wb is provided between the side end of the vertical plate structure 504 and the inner wall surface of the gas supplier 227. The communication portion 520 may be provided partially between the side end of the vertical plate structure 504 and the inner wall surface of the gas supplier 227. Instead of the two convex portions 504A, a convex portion or three or more convex portions may be provided between the side end of the vertical plate structure 504 and the inner wall surface of the gas supplier 227.

In a manner described above, by accommodating the gas guide structure 500 inside the gas supplier 227, the four gas introduction structures 506 arranged side by side in the horizontal direction are configured to allow a part of the gas (which passes through a first one of the gas introduction structures 506 laterally adjacent to a longitudinally middle portion of the gas introduction structures 506) to enter from the first one of the gas introduction structures 506 to a second one of the gas introduction structures 506 via the communication portion 520. In addition, the four gas introduction structures 506 are configured to allow a part of the gas (which passes through the second one of the gas introduction structures 506 adjacent to the first one of the gas introduction structures 506) to enter from the second one of the gas introduction structures 506 to the first one of the gas introduction structures 506 via the communication portion 520.

In addition, the two gas introduction structures 506 arranged in the vertical direction and provided adjacent to each other at both lateral sides of the gas supplier 227 are configured to allow a part of the gas (which passes through an upper one of the two gas introduction structures 506) to enter from the upper one of the two gas introduction structures 506 to a lower one of the two gas introduction structures 506 via the communication portion 518 of the horizontal plate structure 502. In addition, the two gas introduction structures 506 are configured to allow a part of the gas (which passes through the lower one of the two gas introduction structures 506) can enter from the lower one of the two gas introduction structures 506 to the upper one of the two gas introduction structures 506 via the communication portion 518.

As an example, when the gas is supplied to the two gas introduction structures 506 located at both lateral sides of the gas supplier 227, it is possible to eject the gas toward the substrate S through the two gas introduction structures 506 located at both lateral sides of the gas supplier 227, and it is also possible to eject the gas toward the substrate S through the two gas introduction structures 506 located at a laterally central portion of the gas supplier 227. Since the gas introduction structures 506 are partially connected by the communication portion 520 so as to form (or provide) a wide flow symmetrically on left and right, it is possible to supply (or flow) the gas in the wide flow symmetrically on the left and right with the substrate S as a center. In addition, arrows shown in FIG. 2 indicate the flow of the gas. Therefore, it is possible to guide the gas supplied into the gas suppler 227 through the gas supply structure 212 and the gas introduction nozzle 530 by using the gas guide structure 500, and it is also possible to supply the gas to a surface of the substrate S with the gas guided in a manner described above. In addition, each of the communication portion 518 and the communication portion 520 may also be referred to as a “gap” or a “slit”.

### <Downstream Side Gas Guide>

As shown in FIG. 1, the downstream side gas guide 215 is configured such that a ceiling thereof is provided above an uppermost substrate among the substrates S supported by the substrate support 300, and a bottom thereof is provided below a lowermost substrate among the substrates S supported by the substrate support 300.

The downstream side gas guide 215 includes a housing 231 and a plurality of partition plates including a partition plate 232. Hereinafter, the plurality of partition plates including the partition plate 232 may also be simply referred to as “partition plates 232”. A portion of the partition plate 232, which faces the substrate S, extends in the horizontal direction such that a horizontal extending length of the partition plate 232 is at least greater than a diameter of the substrate S. The “horizontal direction” in which the partition plate 232 extends may refer to a direction toward a side wall of the housing 231. In addition, the partition plates 232 are arranged in a multistage manner in the vertical direction in the housing 231. The partition plate 232 is fixed to the side wall of the housing 231 such that it is possible to prevent the gas from flowing into an adjacent region below or above the partition plate 232. By preventing the gas from flowing beyond the partition plate 232, it is possible to reliably form the flow of the gas described later. A flange 233 is provided on a portion of the housing 231 that comes into contact with the gas exhaust structure 213.

The partition plate 232 is a continuous structure without a hole. Center positions between adjacent partition plates among the partition plates 232 correspond to the locations of the substrates S, respectively, and also correspond to vertical centers of the gas suppliers 227, respectively. With such a structure, it is possible to form (or provide) the flow of the gas (which is supplied through each of the gas suppliers 227 and passes over each of the substrates S and each of the partition plates 232), as shown by each arrow in FIG. 1. As described above, the partition plate 232 extends in the horizontal direction and is formed as a continuous structure without a hole. With such a configuration, it is possible to uniformize a pressure loss of the gas ejected (or discharged) through each of the substrates S. Therefore, the flow of the gas passing over each of the substrates S is formed in the horizontal direction toward the gas exhaust structure 213 while suppressing a flow of the gas in the vertical direction.

By providing the partition plates 232 corresponding to the gas suppliers 227, it is possible to uniformize the pressure loss in the vertical direction at both an upstream and a downstream of each of the substrates S. As a result, it is possible to reliably form the flow of the gas in the horizontal direction while the flow of the gas in the vertical direction is suppressed across the gas supplier 227, the substrate S and the partition plate 232.

The gas exhaust structure 213 is provided at a downstream side of the downstream side gas guide 215. The gas exhaust structure 213 is constituted mainly by a housing 241 and a gas exhaust pipe connection structure 242. A flange 243 is provided on a portion of the housing 241 adjacent to the downstream side gas guide 215.

The gas exhaust structure 213 communicates with a space of the downstream side gas guide 215. The housing 231 and the housing 241 are continuous in height. That is, a height of a ceiling of the housing 231 is configured to be the same as that of a ceiling of the housing 241, and a height of a bottom of the housing 231 is configured to be the same as that of a bottom of the housing 241.

The gas that has passed through the downstream side gas guide 215 is exhausted through an exhaust hole 244. When the gas is exhausted through the exhaust hole 244, since the gas exhaust structure 213 is not provided with a structure similar to the partition plate described above, the flow of the gas whose direction includes a vertical component is formed toward the exhaust hole 244.

The transfer chamber 217 is installed in a lower portion of the reaction tube 210 via the manifold 216. In the transfer chamber 217, the substrate S may be transferred to (or placed on) the substrate support 300 (hereinafter, may also be simply referred to as a “boat 300”) by a vacuum transfer robot (not shown), or the substrate S may be transferred out of the substrate support 300 by the vacuum transfer robot.

As shown in FIG. 1, in the transfer chamber 217, the substrate support 300, a partition plate support 310 and a vertical driver (which is a vertical driving structure) 400 can be stored. The vertical driver 400 constitutes a first driver configured to drive the substrate support 300 and the partition plate support 310 in the vertical direction (up-down direction) and in a rotational direction. Hereinafter, the substrate support 300 and the partition plate support 310 may also be collectively referred to as a “substrate retainer”. FIG. 1 is a diagram schematically illustrating a state in which the substrate support 300 is elevated by the vertical driver 400 and stored in the reaction tube 210.

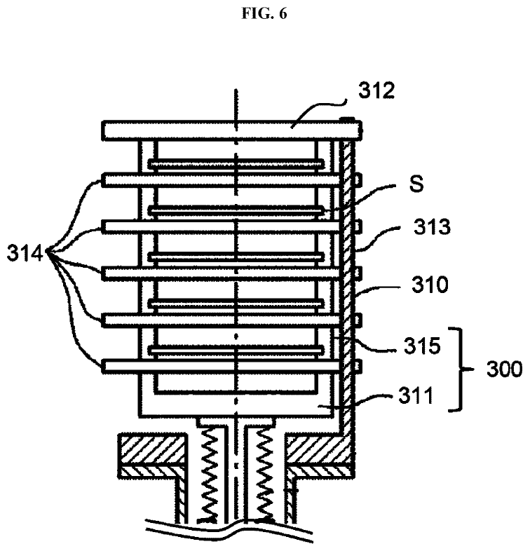

Subsequently, a substrate support structure, which is a structure configured to support the substrate S, will be described in detail with reference to FIGS. 1 and 6. The substrate support structure is constituted by at least the substrate support 300. For example, the substrate support structure is configured such that a process of replacing the substrate S by the vacuum transfer robot in the transfer chamber 217 via a substrate loading/unloading port (not shown) can be performed and a process of loading the substrate S (which is replaced) into the reaction tube 210 such that a film forming process of forming a film on the surface of the substrate S can be performed. In addition, the substrate support structure may further include the partition plate support 310.

A plurality of partition plates including a partition plate 314 of a disk shape are fixed to the partition plate support 310 at a predetermined pitch therebetween at a support column 313 supported between a base structure 311 and a top plate 312. Hereafter, the plurality of partition plates including the partition plate 314 may also be simply referred to as “partition plates 314”. The substrate support 300 includes a configuration in which a plurality of support rods 315 are supported on the base structure 311 and the substrates S are supported by the support rods 315 at a predetermined interval therebetween.

As shown in FIG. 6, the substrates S are placed on the substrate support 300 at the predetermined interval therebetween by the support rods 315 supported by the base structure 311. Spaces between adjacent substrates S among the substrates S supported by the support rods 315 are partitioned by the partition plates 314 (which are of a disk shape) fixed (or supported) at the predetermined interval (pitch) to the support column 313 supported by the partition plate support 310. According to the present embodiments, the partition plate 314 may be provided above or below the substrates S, or the partition plates 314 may be provided above and below the substrates S.

The predetermined interval between the substrates S placed on the substrate support 300 is the same as a vertical interval (that is, the pitch described above) of the partition plates 314 fixed to the partition plate support 310. In addition, a diameter of the partition plate 314 is set to be larger than the diameter of the substrate S.

The substrate support 300 is configured to support a plurality of substrates (for example, 5 substrates) as the substrates S in a multistage manner in the vertical direction by the support rods 315. Each of the base structure 311 and the support rods 315 is made of a material such as quartz and SiC. In addition, the present embodiments will be described by way of an example in which 5 substrates are supported by the substrate support 300 as the substrates S. However, the present embodiments are not limited thereto. For example, the substrate support 300 may be configured to support about 5 substrates to 50 substrates (that is, 5 or more and 50 or less substrates) as the substrates S.

As shown in FIG. 1, the partition plate support 310 and the substrate support 300 are driven by the vertical driver 400 in the vertical direction between the reaction tube 210 and the transfer chamber 217 and in the rotational direction around a center of the substrate S supported by the substrate support 300.

The vertical driver 400 constituting the first driver may include: as drive sources, a vertical driving motor 410; a rotational driving motor 430; and a boat vertical driver 420 provided with a linear actuator serving as a substrate support elevator capable of driving the substrate support 300 in the vertical direction.

### <Gas Supply System>

As shown in FIGS. 2 and 3, for example, according to the present embodiments, various gases can be supplied to the distributors 222 at both lateral sides via the gas supply pipe 251, and various gases can also be supplied to the distributors 222 on the central portion via the gas supply pipe 261.

In addition, components (not shown) such as a mass flow controller (MFC) serving as a flow rate controller (a flow rate control structure) and a valve serving as an opening/closing valve, which are components known in substrate processing apparatuses, are connected to the gas supply pipe 251 at an upstream side of the gas supply pipe 251. In addition, the gas supply system may further include gas supply sources (not shown) which are connected to the gas supply pipe 251 at the upstream side of the gas supply pipe 251.

For example, a second gas supply source of supplying a second gas containing a second element (also referred to as a “second element-containing gas”) and a first gas supply source of supplying the first gas containing a first element (also referred to as the “first element-containing gas”) are connected to the gas supply pipe 251. In addition, an inert gas supply source of supplying an inert gas is connected to the gas supply pipe 251. The inert gas such as nitrogen (N₂) gas is supplied from the inert gas supply source. However, as the inert gas, for example, a gas other than nitrogen (N₂) gas may be used.

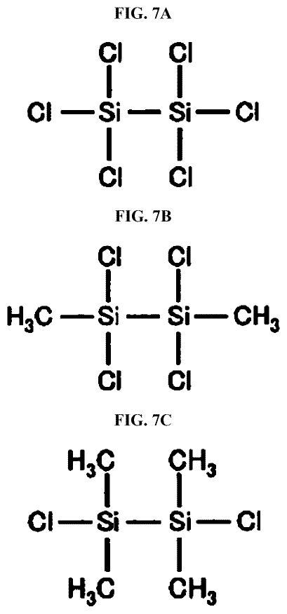

The second gas serves as a source gas, that is, one of process gases. According to the present embodiments, at least two silicon (Si) atoms are bonded in a single molecule of the second gas. For example, the second gas is a gas containing silicon and chlorine (Cl). For example, the second gas is a source gas containing a silicon-silicon (Si—Si) bond such as disilicon hexachloride (Si₂Cl₆, hexachlorodisilane, abbreviated as HCDS) gas shown in FIG. 7A. However, as the second gas, for example, a gas other than the source gas containing the Si—Si bond may be used. As shown in FIG. 7A, the HCDS gas contains silicon and a chloro group (chloride) in its chemical structural formula (in one molecule).

The Si—Si bond contains enough energy to be decomposed by a collision with a wall constituting a concave structure (or a recess) of the substrate S, which will be described later, in the reaction tube 210. According to the present embodiments, the term “decomposed” means that the Si—Si bond is broken. That is, the Si—Si bond is broken by the collision with the wall.

The first gas serves as one of the process gases. Hereinafter, each of the process gases may also be referred to as a “process gas”. In addition, the first gas may serve as a reactive gas or a modification gas.

According to the present embodiments, the first gas serves as an example of the reactive gas, and contains the first element different from the second element of the second gas. For example, the first element may be one of oxygen (O), nitrogen (N) and carbon (C). According to the present embodiments, for example, the first gas is the nitrogen-containing gas. Specifically, the first gas is a hydrogen nitride-based gas containing a nitrogen-hydrogen (N—H) bond such as ammonia (NH₃) gas, diazene (N₂H₂) gas, hydrazine (N₂H₄) gas and N₃H₈ gas. However, as the first gas, for example, a gas other than the hydrogen nitride-based gas may be used.

In addition the inert gas supplied from the inert gas supply source acts as a purge gas for purging the gas remaining in the piping, the gas supplier 227 and the reaction tube 210 when performing a substrate processing described later.

### <Exhaust System>

Subsequently, an exhaust system will be described. As shown in FIG. 1, the exhaust system (not shown) configured to exhaust an inner atmosphere of the reaction tube 210 is connected to the gas exhaust pipe connection structure 242.

For example, the exhaust system includes: a valve serving as an opening/closing valve; an APC (Automatic Pressure Controller) valve serving as a pressure regulator (which is a pressure adjusting structure); and a vacuum pump. With such a configuration, it is possible to vacuum-exhaust the reaction tube 210 such that a pressure (inner pressure) of the reaction tube 210 reaches and is maintained at a predetermined pressure (vacuum degree). The exhaust system may also be referred to as a “process chamber exhaust system”.

### <Controller>

The substrate processing apparatus 100 includes a controller 600 configured to control operations of components constituting the substrate processing apparatus 100.

The controller 600 serving as a control structure (control apparatus) is constituted by a computer including a CPU (Central Processing Unit) 601, a RAM (Random Access Memory) 602, a memory 603 serving as a memory structure and an I/O port (input/output port) 604. The RAM 602, the memory 603 and the I/O port 604 is configured to be capable of exchanging data with the CPU 601 via an internal bus 605. The transmission/reception of the data in the substrate processing apparatus 100 may be performed by an instruction from a transmission/reception instruction controller 606, which is also one of functions of the CPU 601.

A network transmitter/receiver 683 connected to a host apparatus 670 via a network is provided at the controller 600. For example, the network transmitter/receiver 683 is capable of receiving data such as information regarding a processing history and a processing schedule for the substrate S stored in a pod (not shown) from the host apparatus 670.

For example, the memory 603 may be embodied by a component such as a flash memory and a HDD (Hard Disk Drive). For example, a control program for controlling the operations of the substrate processing apparatus 100 or a process recipe in which information such as process procedures and process conditions of the substrate processing is stored may be readably stored in the memory 603.

For example, the process recipe is obtained by combining steps (process procedures) of the substrate processing described later, and acts as a program that is executed by the controller 600 to obtain a predetermined result by performing the steps of the substrate processing described later. Hereinafter, the process recipe and the control program may be collectively or individually referred to simply as a “program”. Thus, in the present specification, the term “program” may refer to the process recipe alone, may refer to the control program alone, or may refer to both of the process recipe and the control program. In addition, the RAM 602 serves as a memory area (for example, a work area) in which the program or the data read by the CPU 601 is temporarily stored.

The I/O port 604 is electrically connected to the components of the substrate processing apparatus 100 described above. The CPU 601 is configured to read and execute the control program from the memory 603, and is configured to read the process recipe from the memory 603 in accordance with an instruction such as an operation command inputted from an input/output device 681. Further, the CPU 601 is configured to be capable of controlling the substrate processing apparatus 100 in accordance with contents of the process recipe read from the input/output device 681.

The CPU 601 includes the transmission/reception instruction controller 606. For example, the controller 600 according to the present embodiments may be embodied by preparing an external memory 682 (for example, a magnetic disk such as a hard disk, an optical disk such as a DVD, a magneto-optical disk such as an MO, a semiconductor memory such as a USB memory) storing the program described above and by installing the program onto the computer by using the external memory 682. However, a method of providing the program to the computer is not limited to that using the external memory 682. For example, the program may be directly provided to the computer by a communication interface such as the Internet and a dedicated line instead of the external memory 682. In addition, the memory 603 and the external memory 682 may be embodied by a non-transitory computer-readable recording medium. Hereinafter, the memory 603 and the external memory 682 may be collectively or individually referred to as a “recording medium”. Thus, in the present specification, the term “recording medium” may refer to the memory 603 alone, may refer to the external memory 682 alone, or may refer to both of the memory 603 and the external memory 682.

### <Substrate Processing>

Hereinafter, as a part of a manufacturing process of a semiconductor device, the substrate processing will be described by way of an example in which the film forming process of forming a film on the substrate S is performed by using the substrate processing apparatus 100 described above. In the following description, the controller 600 controls the operations of the components constituting the substrate processing apparatus 100.

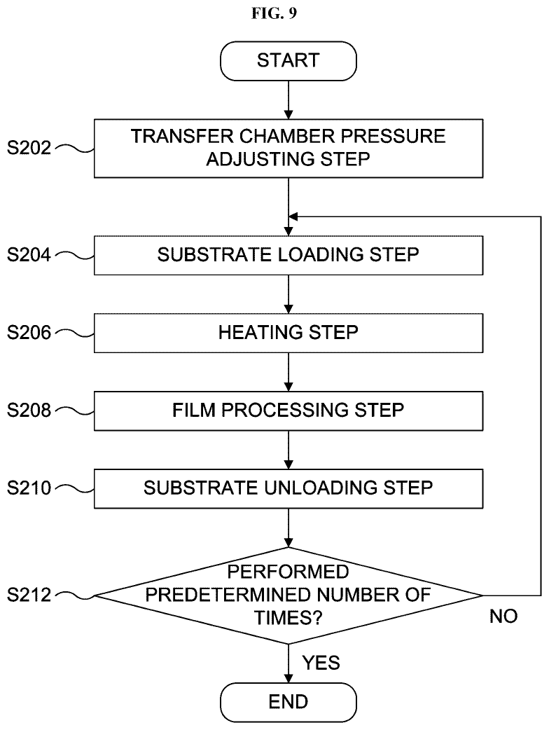

For example, the film forming process of forming the film on the substrate S by alternately supplying the second gas and the first gas will be described with reference to FIG. 9.

### <Step S202>

First, a transfer chamber pressure adjusting step S202 will be described. In the present step, a pressure (inner pressure) of the transfer chamber 217 is set to a pressure of a vacuum level. Specifically, by operating an exhaust system (not shown) connected to the transfer chamber 217, an atmosphere (inner atmosphere) of the transfer chamber 217 is exhausted such that the inner pressure of the transfer chamber 217 reaches and is maintained at the vacuum level.

In addition, the heater 211 may be operated in parallel with the present step. When the heater 211 is operated, the heater 211 is continuously operated at least during a film processing step S208 described later.

### <Step S204>

Subsequently, a substrate loading step S204 (which is an example of a step of loading the substrate S according to the present disclosure) will be described. After the inner pressure of the transfer chamber 217 reaches the vacuum level, the substrate S is loaded (transferred) from the vacuum transfer chamber (not shown) adjacent to the transfer chamber 217 into the transfer chamber 217.

In the present step, the substrate support 300 stands by in the transfer chamber 217, and the substrate S is transferred to the substrate support 300. When a predetermined number of the substrates S are transferred to the substrate support 300, the vacuum transfer robot (not shown) is retracted, and the substrate support 300 is elevated to move the substrates S into the reaction tube 210.

When moving the substrate S into the reaction tube 210, a position of the substrate S is determined such that a height of the surface of the substrate S is aligned with a height of the gas supplier 227.

### <Step S206>

Subsequently, a heating step S206 will be described. When the substrate S is loaded into the reaction tube 210, a surface temperature of the substrate S is controlled to be a predetermined temperature by controlling the heater 211. For example, the predetermined temperature (that is, the surface temperature) is a temperature within a high temperature range described later. For example, the substrate S is heated to the temperature within a range from 400° C. to 800° C. Preferably, the substrate S is heated to the temperature within a range from 500° C. to 700° C. However, the predetermined temperature is not limited thereto. For example, in the present specification, a notation of a numerical range such as 400° C. to 800° C.” means that a lower limit and an upper limit are contained in the numerical range. Therefore, for example, a numerical range “400° C. to 800° C.” means a range equal to or higher than 400° C. and equal to or less than 800° C. The same also applies to other numerical ranges described in the present specification.

### <Step S208>

Subsequently, the film processing step S208 will be described. After the heating step S206, the film processing step S208 is performed. In the film processing step S208, in accordance with the process recipe, the second gas is ejected through the ejection holes 222c on both sides of the gas supply structure 212 into the gas supplier 227 (the two gas introduction structures 506 at both lateral sides, that is, the second gas supply path of the present disclosure) and supplied into the reaction tube 210. In addition, the exhaust system is controlled to exhaust the process gas from inside the reaction tube 210. Thereby, a film processing is performed. The film processing step S208 corresponds to a step of supplying the process gas to the substrate S of the present disclosure. In addition, the ejection holes 222c on both sides of the gas supply structure 212 serve as an example of the second gas introduction port of the present disclosure.

In the present step, for example, an alternate supply process is performed by alternately supplying the second gas and the first gas into the reaction tube 210. The gases are supplied and exhausted into the reaction tube 210 such that the inner pressure of the reaction tube 210 is maintained at a predetermined pressure.

The following method may be used as the alternate supply process serving as a specific example of a film processing method. For example, a first step of supplying the second gas into the reaction tube 210, a second step of supplying the first gas into the reaction tube 210 and a purge step of supplying the inert gas into the reaction tube 210 and exhausting the inner atmosphere of the reaction tube 210 between the first step and the second step may be performed. That is, a desired film is formed by performing the alternate supply process in which a combination of the first step, the purge step and the second step is performed a plurality number of times.

When the gas is supplied, the flow of the gas is formed over the gas supplier 227, a space on the substrate S and the downstream side gas guide 215. That is, the flow of the gas most suitable for processing the substrate S is formed.

For example, when the second gas is supplied into the reaction tube 210, the second gas is supplied through the distributors 222 on both sides of the gas supply structure 212 toward the gas supplier 227. The second gas supplied through the distributors 222 is ejected through the ejection holes 222c on both sides to the gas introduction structures 506 on both sides of the gas supplier 227. Then, a part of the second gas flows (or is supplied) to the gas introduction structures 506 provided on the central portion of the gas supplier 227 via the communication portion 520 of the vertical plate structure 504.

As a result, it is possible to finally discharge (or exhaust) the same amount of the second gas at the same speed along the surface of the substrate S through downstream ends of the gas introduction structures 506 on both sides and through downstream ends of the gas introduction structures 506 on the central portion. The second gas is ejected horizontally through the gas suppler 227 and supplied in parallel along the surface of the substrate S horizontally arranged. Thereby, it is possible to uniformly process the surface of the substrate S.

In addition, as shown in FIG. 1, the gas suppliers 227 are provided in a multistage manner in the height direction of the substrate retainer, and the gas supplier 227 are provided for the substrates S, respectively. Thereby, it is possible to uniformly perform a process on the substrates S.

As shown in FIG. 4, in the gas supplier 227, by setting the width Wb of the communication portion 520 within a range from 5% 10% of a lateral width WA of the gas introduction structure 506, it is possible to optimize the amount of the gas entering from the gas introduction structures 506 at both lateral sides of the gas supplier 227 to the gas introduction structures 506 at the laterally central portion of the gas supplier 227. Thereby, it is possible to uniformize the amount and speed of the second gas discharged through each of the gas introduction structures 506 toward the substrate S, and it is also possible to increase an average flow velocity of the gas discharged through each of the gas introduction structures 506.

When the first gas is supplied into the reaction tube 210, it is possible to guide the flow of the gas by the gas guide structure 500 in the same manner as when the second gas is supplied into the reaction tube 210, and it is possible to uniformly process an entire surface of the substrate S. When the first gas is supplied into the reaction tube 210, the first gas is ejected through the front end 530A of the gas introduction nozzle 530 into the two the gas introduction structures 506 (that is, the first gas supply path of the present disclosure) on the laterally central portion of the gas supplier 227. Then, a part of the first gas ejected through the front end 530A flows (or is supplied) to the gas introduction structures 506 on both sides of the gas supplier 227 via the communication portion 520 of the vertical plate structure 504. As a result, it is possible to finally discharge (or exhaust) the same amount of the first gas at the same speed along the surface of the substrate S through the downstream ends of the gas introduction structures 506 on the central portion and through the downstream ends of the gas introduction structures 506 on both sides.

Incidentally, when the second gas and the first gas are alternately supplied into the reaction tube 210, for example, after a supply of the first gas is stopped, a part of the first gas may adhere to the gas supplier 227 and the gas guide structure 500. In such a state, when the second gas is subsequently supplied into the gas supplier 227, the first gas adhering to the gas supplier 227 and the gas guide structure 500 may react with the second gas supplied later. Thereby, particles (that is, undesired impurities produced by a reaction between the second gas and the first gas) may be generated in the gas supplier 227.

According to the present embodiments, the front end 530A of the gas introduction nozzle 530 is disposed at the location where the temperature of the location is high enough such that the nitrogen-containing gas serving as the first gas is prevented from adhering to the gas suppler 227 and the gas guide structure 500. Therefore, the nitrogen-containing gas introduced (supplied) into the reaction tube 210 through the gas introduction nozzle 530 does not adhere to the gas supplier 227 and gas guide structure 500, and the reaction between the first gas and the second gas remaining in the gas supplier 227 and the gas guide structure 500 can be suppressed. As a result, it is possible to suppress a generation of the particles in the gas suppler 227. In addition, since the generation of the particles can be suppressed, an adhesion of the particles to the substrate S can also be suppressed. As a result, it is possible to obtain the substrate S with a high quality after processing the substrate S.

For example, when the ammonia (NH₃) gas is used as the nitrogen-containing gas serving as the first gas, in order to prevent the ammonia gas from adhering to the gas supplier 227 and the gas guide structure 500, it is preferable to eject the ammonia gas at a location where temperatures of the gas supplier 227 and the gas guide structure 500 reach 400° C. or higher (that is, a high temperature location where the ammonia gas does not adhere). In other words, the ammonia gas is likely to adhere to the location whose temperature is less than 400° C.

According to the present embodiments, as shown in FIG. 2, the front end 530A of the gas introduction nozzle 530 is disposed at a location where the temperatures of the gas supplier 227 and the gas guide structure 500 reach 550° C. (a location indicated by a dash-double dotted line in FIG. 2) such that ammonia gas is ejected through the location where the temperatures of the gas supplier 227 and the gas guide structure 500 reach 550° C.

In addition, for example, when the HCDS gas is uses as the second gas, it is preferable that the surface temperature of the substrate S and a temperature (inner temperature) of the gas supplier 227 are set to be 800° C. or less. When the temperatures are higher than 800° C., the HCDS gas will decompose.

### <Step S210>

Subsequently, a substrate unloading step S210 will be described. In the substrate unloading step S210, the substrates S processed as described above are transferred (unloaded) out of the transfer chamber 217 in an order reverse to that of the substrate loading step S204 described above.

### <Step S212>

Subsequently, a determination step S212 will be described. In the present step, it is determined whether or not a processing described above (that is, the step S204 through S210) has been performed a predetermined number of times. When it is determined that the processing has not been performed the predetermined number of times, the substrate loading step S204 is performed again to process a subsequent substrate S to be processed. When it is determined that the processing has been performed the predetermined number of times, the substrate processing is terminated.

In addition, in the above, various expressions such as “the same”, “similar” and the like are used. However, it goes without saying that the expressions described above may mean “substantially the same”.

For example, when the gas introduction nozzle 530 is not provided and the ammonia gas (that is, the first gas) is ejected through the side surface of the gas supply structure 212 into the gas supplier 227, the ammonia gas may pass through a low temperature location (whose temperature is less than 400° C.) of the gas supplier 227. Thereby, the particles may be generated in the vicinity of the gas supply structure 212. On the other hand, according to the present embodiments, since the ammonia gas is ejected through a high temperature location where the temperatures of the gas supplier 227 and the gas guide structure 500 reach 400° C. or higher, the ammonia gas does not adhere to the gas supplier 227 and the gas guide structure 500. As a result, it is possible to suppress the generation of the particles.

In addition, the embodiments mentioned above are described by way of an example in which the ammonia gas is ejected into the gas supplier 227. However, when a gas other than ammonia gas is ejected as the first gas, the first gas is ejected through a high temperature location where the first gas does not adhere. In other words, the front end 530A of the gas introduction nozzle 530 is disposed at the high temperature location where the first gas does not adhere.

Incidentally, when the ammonia gas (that is, the first gas) is supplied through the two gas introduction structures 506 at the laterally central portion of the gas supplier 227, the inert gas may be supplied through the two gas introduction structures 506 on both sides of the gas supplier 227 in the width direction. By supplying the inert gas, it is possible to dilute the ammonia gas. In addition, when the HCDS gas (that is, the second gas) is supplied through the two gas introduction structures 506 on both sides of the gas supplier 227 in the width direction, the inert gas may be supplied through the two gas introduction structures 506 on the central portion of the gas supplier 227. By supplying the inert gas, it is possible to dilute the HCDS gas.

As described above, according to the embodiments of the present disclosure, it is possible to obtain one or more of the effects described above.

### Other Embodiments of Present Disclosure

The technique of the present disclosure is described in detail by way of the embodiments mentioned above. However, the technique of the present disclosure is not limited thereto, and may be modified in various ways without departing from the scope thereof.

For example, the embodiments mentioned above are described by way of an example in which, in the film forming process performed by the substrate processing apparatus 100, the film is formed on the substrate S by using the first gas and the second gas. However, the technique of the present disclosure is not limited thereto. That is, as the process gases used in the film forming process, other gases may be used to form different films. In addition, the technique of the present disclosure may also be applied to film forming processes using three or more different process gases as long as the three or more different process gases are non-simultaneously supplied (that is, supplied in a non-overlapping manner) to form various films. Specifically, as the first element, for example, an element such as titanium (Ti), silicon (Si), zirconium (Zr) and hafnium (Hf) may be used. In addition, for example, as the second element, for example, an element such as nitrogen (N) and oxygen (O) may be used. However, as mentioned above, it is preferable to use silicon (Si) as the first element.

For example, the embodiments mentioned above are described by way of an example in which the HCDS gas is used as an example of the second gas. However, the second gas is not limited thereto. As the second gas, for example, a gas containing silicon and further containing a Si—Si bond may be used. As the second gas, for example, a gas such as tetrachloro dimethyl disilane ((CH₃)₂Si₂Cl₄, abbreviated as TCDMDS) and dichloro tetramethyl disilane ((CH₃)₄Si₂Cl₂, abbreviated as DCTMDS) may be used. As shown in FIG. 7B, the TCDMDS contains a Si—Si bond and further contains a chloro group and an alkylene group. In addition, as shown in FIG. 7C, the DCTMDS contains a Si—Si bond and further contains a chloro group and an alkylene group.

For example, the embodiments mentioned above are described by way of an example in which the film forming process is performed by the substrate processing apparatus. However, the technique of the present disclosure is not limited thereto. That is, the technique of the present disclosure may be applied not only to the film-forming process of forming the film exemplified in the embodiments mentioned above but also to other film-forming processes of forming other films.

In addition, one or more constituents of the embodiments mentioned above may be substituted with one or more constituents of other embodiments, or may be added to other embodiments. Further, a part of one or more constituents of the embodiments mentioned above may be omitted, or substituted with or added by other constituents.

For example, in the embodiments mentioned above, the four gas introduction structures 506 are arranged inside the gas supplier 227 in the width direction of the gas supplier 227. However, the number of the vertical plate structures 504 provided in the gas guide structure 500 may be increased to provide five or more gas introduction structures 506 in the width direction of the gas supplier 227, and the number of the gas guide structures 500 may be increased or decreased as appropriate. Even in such a case, it is possible to supply the gas to at least two of the gas introduction structures among the gas introduction structures 506. In addition, the gas may also be supplied to three or more of the gas introduction structures among the gas introduction structures 506 as appropriate.

For example, in the embodiments mentioned above, the gas guide structure 500 is disposed inside the gas supplier 227, and the inside of the gas supplier 227 is divided vertically into two with the four gas introduction structures 506 provided side by side on each of upper and lower sides thereof. However, the inside of the gas supplier 227 may be divided into upper and lower portions as appropriate. Alternatively, the inside of the gas supplier 227 may not be divided into upper and lower portions.

The communication portion 518 and the communication portion 520 may be provided at appropriate locations such that it is possible to supply the process gas in the wide flow symmetrically on the left and right with the substrate S as the center.

The gas suppliers 227 may be stacked in accordance with the number of the substrates S to be processed. When processing one substrate S, one gas supplier 227 may be sufficient. That is, the technique of the present disclosure may also be applied when processing one substrate S. Even in such a case, it is possible to obtain substantially the same effects as in the embodiments mentioned above.

For example, in the embodiments mentioned above, the gas guide structure 500 is constituted by the plate structures mentioned above. However, the gas guide structure 500 may be constituted by structures other than the plate structures.

In the present specification, the term “substrate” may refer to “a substrate itself” or may refer to “a substrate and a stacked structure (aggregated structure) of a predetermined layer (or layers) or a film (or films) formed on a surface of the substrate”. In addition, in the present specification, the term “a surface of a substrate” may refer to “a surface of a substrate itself” or may refer to “a surface of a predetermined layer (or layers) or a film (or films) formed on a substrate”. Thus, in the present specification, the term “forming a predetermined layer (or a film) on a substrate” may refer to “forming a predetermined layer (or a film) on a surface of a substrate itself” or may refer to “forming a predetermined layer (or a film) on a surface of another layer (or another film) formed on the substrate”. In the present specification, the terms “substrate” and “wafer” may be used as substantially the same meaning.

Further, although not specifically described in the embodiments mentioned above, the number of each component described in the embodiments mentioned above is not limited to one, and the number of each component may be two or more unless otherwise specified in the present specification.

For example, the embodiments mentioned above are described by way of an example in which a substrate processing apparatus capable of simultaneously processing a plurality of substrates is used to form the film. However, the technique of the present disclosure is not limited thereto. For example, the technique of the present disclosure may be preferably applied when a substrate processing apparatus capable of processing one substrate at once is used to form the film. For example, the technique of the present disclosure may be preferably applied to a substrate processing apparatus including a hot wall type process furnace or a substrate processing apparatus including a cold wall type process furnace. In addition, the technique of the present disclosure may also be applied to a substrate processing apparatus provided with a nozzle through which the process gas is ejected along the substrate.

Process procedures and process conditions of each process using the substrate processing apparatuses exemplified above may be substantially the same as those of the embodiments or modified examples mentioned above. Even in such a case, it is possible to obtain substantially the same effects as in the embodiments or the modified examples mentioned above. Further, the embodiments and the modified examples mentioned above may be appropriately combined. The process procedures and the process conditions of each combination thereof may be substantially the same as those of the embodiments mentioned above or the modified examples mentioned above.

According to some embodiments of the present disclosure, it is possible to suppress the generation of the particles in the gas supply path.

What is claimed is:

1. A substrate processing apparatus comprising:
a process chamber in which a substrate is processed;
a first gas supply path through which a first gas is supplied to the substrate from beside the process chamber; and
a first gas introduction port provided at a location heated to a predetermined temperature within the first gas supply path, wherein the first gas is introduced into the first gas supply path through the first gas introduction port.

2. The substrate processing apparatus of claim 1, wherein the first gas introduction port is provided in a first gas introduction structure disposed in the first gas supply path.

3. The substrate processing apparatus of claim 2, wherein the first gas introduction structure comprises a nozzle, and the first gas introduction port is provided at a front end of the nozzle.

4. The substrate processing apparatus of claim 3, wherein the front end of the nozzle is provided at the location of the predetermined temperature.

5. The substrate processing apparatus of claim 1, further comprising:
a second gas supply path through which a second gas different from the first gas is supplied to the substrate from beside the process chamber; and
a second gas introduction port through which the second gas is introduced into the second gas supply path.

6. The substrate processing apparatus of claim 5, wherein a distance between the first gas introduction port and the substrate is set to be shorter than a distance between the second gas introduction port and the substrate.

7. The substrate processing apparatus of claim 5, further comprising
a housing structure provided at a side surface of the process chamber and configured to accommodate a gas supply assembly comprising the first gas supply path and the second gas supply path.

8. The substrate processing apparatus of claim 7, further comprising
a partition wall provided between the first gas supply path and the second gas supply path.

9. The substrate processing apparatus of claim 7, wherein the first gas supply path and the second gas supply path are provided adjacent to each other.

10. The substrate processing apparatus of claim 7, wherein the process chamber is configured to accommodate a substrate retainer in which the substrate and one or more substrates are stacked and supported, and
wherein the housing structure is configured to accommodate the gas supply assembly and one or more gas supply assemblies in a state where the gas supply assembly and one or more gas supply assemblies are stacked.

11. The substrate processing apparatus of claim 7, further comprising
a heater configured to heat the housing structure.

12. The substrate processing apparatus of claim 1, wherein the first gas comprises a reactive gas.

13. The substrate processing apparatus of claim 12, wherein the reactive gas comprises a nitrogen-containing gas.

14. The substrate processing apparatus of claim 13, wherein the predetermined temperature is a temperature at which the nitrogen-containing gas is prevented from adhering to the first gas supply path.

15. The substrate processing apparatus of claim 5, wherein an inert gas is supplied to the second gas supply path while the first gas is being supplied to the first gas supply path.

16. The substrate processing apparatus of claim 5, wherein an inert gas is supplied to the first gas supply path while the second gas is being supplied to the second gas supply path.

17. A gas supply assembly comprising:
a first gas supply path through which a first gas is supplied to a substrate from beside a process chamber in which the substrate is processed; and
a first gas introduction port provided at a location heated to a predetermined temperature within the first gas supply path, wherein the first gas is introduced into the first gas supply path through the first gas introduction port.

18. A substrate processing method comprising
supplying a first gas to a substrate in a process chamber through a first gas introduction port,
wherein the first gas introduction port is provided at a location heated to a predetermined temperature within a first gas supply path through which the first gas is supplied.

19. A method of manufacturing a semiconductor device, comprising
the method of claim 18.

20. A non-transitory computer-readable recording medium storing a program that causes a substrate processing apparatus, by a computer, to perform a process comprising the method of claim 18.
